(19) United States
(12) Patent Application Publication
(10) Pub. No.: US 2011/0134619 A1
(43) Pub. Date: Jun. 9, 2011

(54) High power device module

(76) Inventor: Chin-Feng Lin, Hsintien (TW)

(21) Appl. No.: 11/976,602

(22) Filed: Oct. 25, 2007

(51) Int. Cl. H05K 7/00

(52) U.S. Cl. 361/783

(57) ABSTRACT

A high power device module includes a substrate carrying multiple chips on the top side and having stepped through holes around the chips, copper plates and connectors connected to the chips, fastening members each having a shoulder respectively fitted into the through holes of the substrate, a head connected to one end of the shoulder fitted into the expanded bottom end of the associating stepped through hole, and a shank connected to the other end of the shoulder and protruding over the top side of the substrate, and packaging members directly molded from resin on the shanks of the fastening members and the chips and the copper plates and the connectors to seal the component parts to the substrate.

### BACKGROUND OF THE INVENTION

1. Field of the Invention

The present invention relates to a high power device module for high power application and more particularly, to such a high power device module, which is strong enough to bear a high gravity weight.

2. Description of the Related Art

Following the development and integration of technology, power electronic devices and control techniques are well developed. In addition to the application for electric energy conversion and energy saving, power electronic technology has also been intensively used in many other different fields to improve our living quality. Facing global free dissemination of electrical industry, utilization of recycling energy and development of new energy, advanced countries are trying hard in integration of power supply, electronics, and electromechanics.

FIG. 6 illustrates the internal structure of a conventional high power device module. According to this design, screws 20 are mounted in a substrate 10 to reinforce the structure of the module. The screws 20 are threaded into the top wall of the substrate 20, and kept in vertical. After installation of chips, copper plates and connectors (not shown) in the substrate 20, packaging members are molded from a resin on the screws 20 and the other component parts. This design of high power device module is still not satisfactory in function. During application, the gravity weight of the electric power device that is connected to the high power device module may cause disconnection of the screws 20 from the substrate 10. When this condition happened, the high power device module must be replaced with a new one.

### SUMMARY OF THE INVENTION

The present invention has been accomplished under the circumstances in view. It is the main object of the present invention to provide a high power device module, which has a high tensile strength for high power application. According to the present invention, the substrate of the high power device module has a plurality of stepped through holes, and the fastening members that are fastened to the substrate around the chips at the substrate for the molding of packaging members to seal the chips and the related component parts to the substrate are respectively fitted into the stepped through holes and partially protruding over the top side of the substrate for positive molding of the packaging members. When in use, the gravity weight of the electric power device that is connected to the connectors in the packaging members or any accidental stretching force given to the electric power device will never cause separation of the fastening members from the substrate.

### BRIEF DESCRIPTION OF THE DRAWINGS

FIG. 1 is an elevational view of a high power device module in accordance with the present invention.

FIG. 2 is an elevational view of the high power device module before molding of the packaging members.

FIG. 3 is an exploded view of a part of the high power device module according to the present invention.

FIG. 4 is an oblique elevation of a part of the high power device module in accordance with the present invention, showing the fastening members installed in the substrate.

FIG. 5 is a sectional view taken along line 5-5 of FIG. 4.

FIG. 6 is an oblique elevation of a part of a prior art high power device module, showing a plurality of fastening members installed in a substrate.

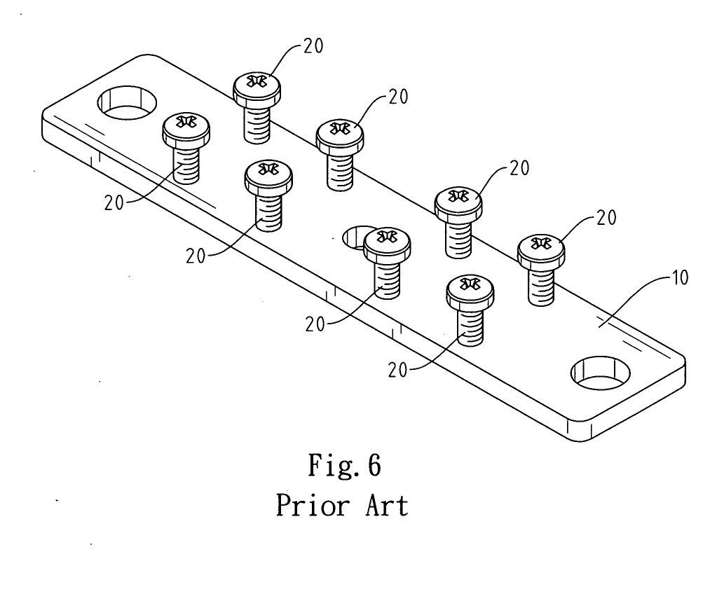

### DETAILED DESCRIPTION OF THE PREFERRED EMBODIMENT

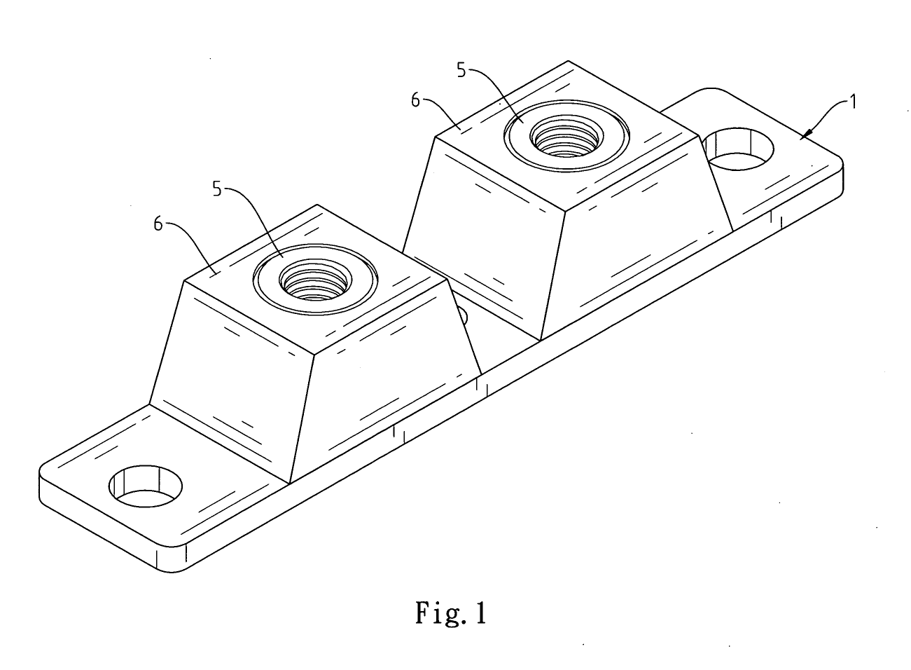

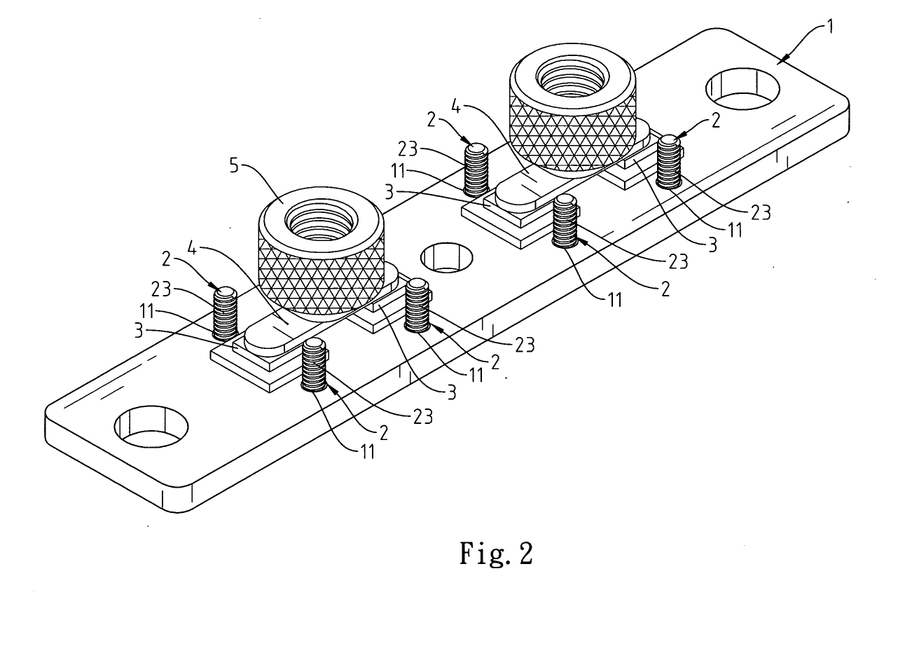

Referring to FIGS. 1-3, a high power device module in accordance with the present invention is shown comprising a substrate 1, and a plurality of fastening members 2 installed in the substrate 1. The substrate 1 has a plurality of through holes 11 cut through its top and bottom sides. The through holes 11 are stepped through holes, each having an expanded bottom end 111. The fastening members 2 are respectively mounted in the through holes 11 of the substrate 1, each comprising a head 21, a shank 23, and a shoulder 22 connected between the shank 23 and the head 21.

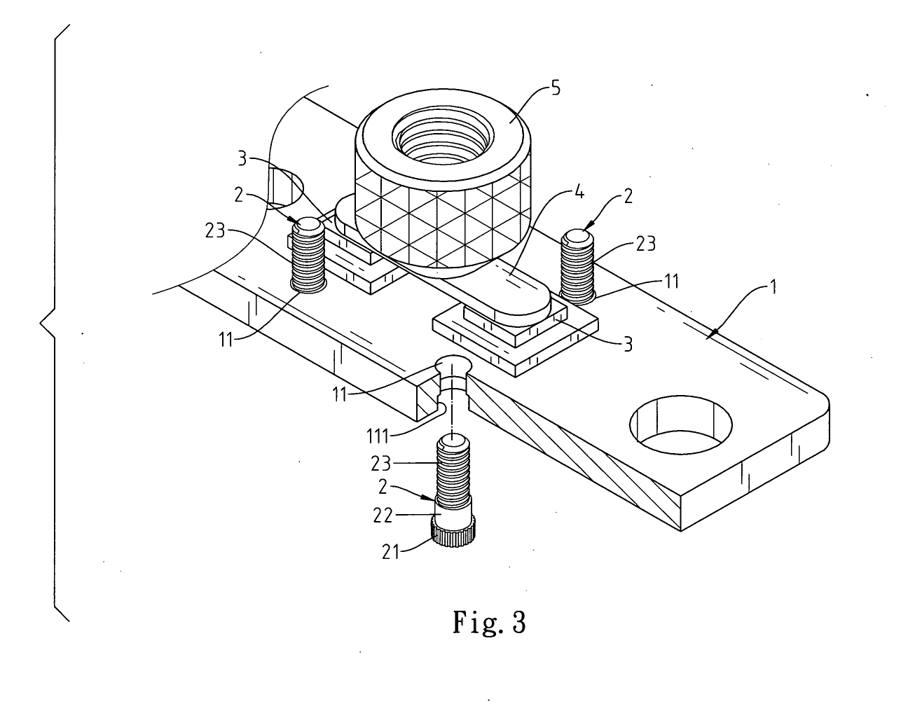

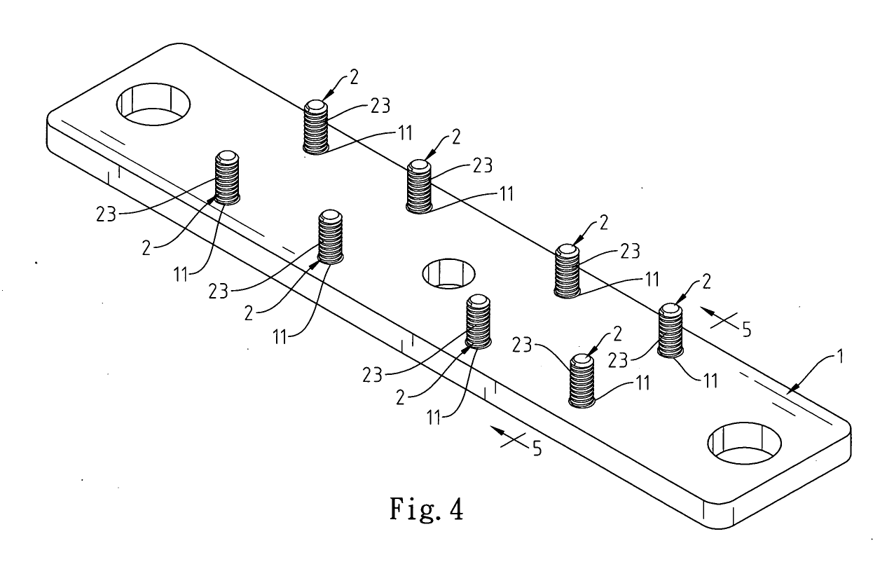

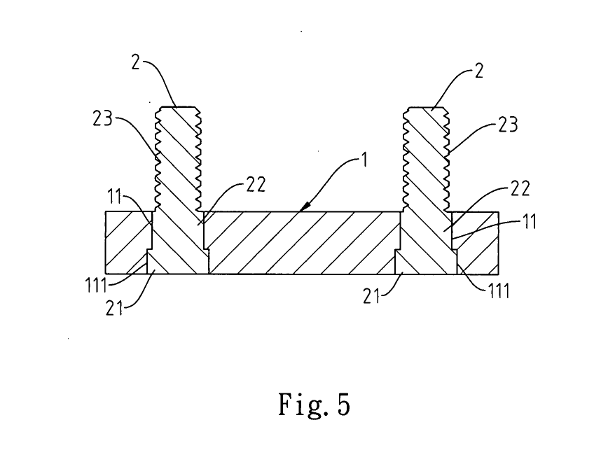

Referring to FIGS. 4 and 5 and FIG. 3 again, the fastening members 2 are respectively inserted into the through holes 11 from the bottom side of the substrate 1 to have the respectively shoulders 22 respectively fitted into the through holes 11 and the respective heads 21 respectively fitted into the expanded bottom ends 111 of the through holes 11 and the respective shanks 23 protruding over the top side of the substrate 1. Because the through holes 11 are stepped through holes and the heads 21 of the fastening members 2 are respectively positioned in the expanded bottom ends 111 of the through holes 11, the fastening members 2 will never be pulled away from the substrate 1 in direction from the bottom side of the substrate 1 toward the top side of the substrate 1.

Referring to FIGS. 1 and 3 again, after installation of the fastening members 2 in the substrate 1, chips 3 are installed in the substrate 1, and then copper plates 4 are connected to the chips 3, and then connectors 5 are connected to the copper plates 4, and packaging members 6 are directly molded from a resin on the fastening members 2 and the connectors 5 to have the chips 3 embedded therein. After package, the connectors 5 are partially exposed to the outside of the packaging members 6 for the connection of an electric power device

As stated above, the fastening members 2 are mounted in the stepped through holes 11 with the respective heads 21 respectively fitted into the expanded bottom ends 111 of the through holes 11. After molding of the packaging members 6, the fastening members 2 with the chips 3 and the copper plates 4 as well as the connectors 5 are positively secured to the substrate 1. Therefore, any stretching force applied to the electric power device that is electrically connected to the connectors 5 does not cause separation of the fastening members 2 from the substrate 1.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A high power device module comprising a substrate, said substrate having a top side and a bottom side opposite to said top side, a plurality of chips installed in the top side of said substrate, a plurality of copper plates and connectors connected to said chips, a plurality of fastening members mounted in said substrate around said chips, and a plurality of packaging members molded on said fastening members, said chips, said copper plates and said connectors, wherein said substrate comprise a plurality of stepped through holes cut through top and bottom sides thereof, said stepped through holes each having an expanded bottom end said fastening members each comprise a shoulder respectively fitted into said stepped through holes, a shank extending from said shoulder and protruding over the top side of said substrate and respectively embedded in packaging members, and a head connected to said shoulder opposite to said shank and respectively fitted into the expanded bottom end of said stepped through holes.
